(19) United States
(12) Patent Application Publication
(10) Pub. No.: US 2021/0166960 A1
(43) Pub. Date: Jun. 3, 2021

(54) JIG, PROCESSING SYSTEM AND PROCESSING METHOD

(71) Applicant: Tokyo Electron Limited, Tokyo (JP)

(72) Inventors: Kippei SUGITA, Miyagi (JP); Masaaki MIYAGAWA, Miyagi (JP); Masashi YAMAGUCHI, Miyagi (JP)

(21) Appl. No.: 17/105,753

(22) Filed: Nov. 27, 2020

(30) Foreign Application Priority Data
Nov. 29, 2019 (JP) 2019-217362
Oct. 6, 2020 (JP) 2020-169174

(51) Int. Cl. H01L 21/67; H01J 37/32; C23C 16/52; C23C 16/455; G01J 3/443

(52) U.S. Cl. CPC H01L 21/67253; H01J 37/32788; H01J 37/32899; C23C 16/52; C23C 16/45536; H01L 21/67196; G01J 3/443; H01J 2237/184; H01J 2237/2445; H01J 2237/24592; H01L 21/67069; C23C 16/45544

(57) ABSTRACT

A jig includes a base, light sources disposed on the base, the sources configured to emit light of different wavelengths, a controller disposed on the base, the controller being configured to cause the light sources to be turned on or off based on a given program, and a power source disposed on the base, the power source being configured to supply power to the light sources and the controller. The jig has a shape enabling a transfer device to transfer the jig, the transfer device being provided in a vacuum transfer module and configured to transfer a substrate.

### CROSS-REFERENCE TO RELATED APPLICATIONS

This patent application claims priority to Japanese Patent Application No. 2019-217362, filed Nov. 29, 2019, and Japanese Patent Application No. 2020-169174, filed Oct. 6, 2020, the entire contents of which are incorporated herein by reference in their entirety.

### TECHNICAL FIELD

The present disclosure relates to a jig, a processing system, and a processing method.

### BACKGROUND

Japanese Unexamined Patent Publication No. 2011-517097, which is hereinafter referred to as Patent document 1, discloses a plasma processing apparatus having a chamber connected to an optical emission spectrometer. The plasma processing apparatus monitors and controls a process through analysis of intensity of a spectrum created in the chamber. Japanese Translation of PCT International Application Publication No. 2018-91836, which is hereinafter referred to Patent document 2, discloses a system in which an optical calibration apparatus with a light source such as a xenon lamp that provides a continuous spectrum is disposed in a chamber. The system calibrates the optical calibration apparatus.

The present disclosure provides a technique that increases analytic accuracy of emission intensity.

### SUMMARY

According to one aspect in the present disclosure, a jig is provided, including a base; light sources disposed on the base, the sources being configured to emit light of different wavelengths; a controller disposed on the base, the controller being configured to cause the light sources to be turned on or off based on a given program; and a power source disposed on the base, the power source being configured to supply power to the light sources and the controller, wherein the jig has a shape enabling a transfer device to transfer the jig, the transfer device being provided in a vacuum transfer module and configured to transfer a substrate.

### BRIEF DESCRIPTION OF THE DRAWINGS

FIG. 1 is a cross-sectional view schematically illustrating an example of a jig according to an embodiment;

FIG. 2 is a diagram illustrating an example of a plasma processing apparatus according to the embodiment;

FIG. 3 is a diagram illustrating an example of a semiconductor manufacturing apparatus according to the embodiment;

FIG. 4 is a diagram illustrating an example of a hardware configuration of a given processing system including a given semiconductor manufacturing apparatus according to the embodiment;

FIG. 5 is a diagram illustrating an example of a hardware configuration of a given processing system including a given semiconductor manufacturing apparatus according to the embodiment;

FIG. 6 is a diagram illustrating an example of the operation of the processing system according to the embodiment;

FIG. 7 is a diagram illustrating an example of reference data according to the embodiment;

FIG. 8 is a diagram illustrating an example of the operation of an optical emission spectrometer according to the embodiment;

FIG. 9 is a diagram illustrating an example of the operation of the processing system according to the embodiment;

FIG. 10 is a diagram for describing another example of analysis using the processing system according to the embodiment; and

FIG. 11 is a cross-sectional view schematically illustrating another example of the jig according to the embodiment.

### DETAILED DESCRIPTION

Hereinafter, one or more embodiments of the present disclosure will be described with reference to the drawings. In each drawing, the same components are denoted by the same numerals, and duplicate descriptions may be omitted.

### Jig

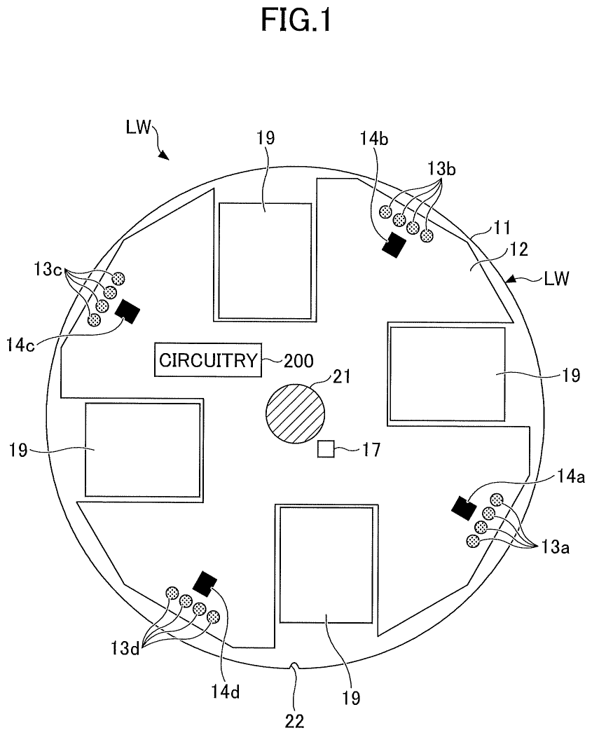

A jig LW according to the embodiment will be described with reference to FIG. 1. FIG. 1 is a cross-sectional diagram schematically illustrating an example of the jig LW according to the embodiment. The jig LW includes a base 11, a control board 12, a plurality of light sources 13a to 13d (which are also collectively referred to as “light sources 13”), batteries 19, and a plurality of temperature sensors 14a to 14d (which are also collectively referred to as “temperature sensors 14”).

The base 11 is an evaluation substrate (e.g., bare silicon), and a disk-shaped wafer is used as an example of the evaluation substrate. The base 11 is distinguished from a substrate (e.g., product substrate). However, the shape of the base 11 is not limited to a disc shape. Any shape of the base 11 such as a polygon or an ellipse may be adopted when the base can be transferred by a transfer device that transfers the substrate. According to the embodiment, in a processing system described below, the jig LW has a shape enabling the transfer device, which is provided in a vacuum transfer module, to transfer the jig. In such a configuration, the jig LW can be transferred between an apparatus such as a plasma processing apparatus, and the transfer component, without breaking the vacuum. Examples of material of the evaluation substrate include silicon, carbon fiber, quartz glass, silicon carbide, silicon nitride, alumina, and the like. Preferably, the substrate material is a material having electrical conductivity and thermal conductivity.

The control board 12 is a circuit board disposed on the base 11, and includes light sources 13a to 13d, temperature sensors 14a to 14d, a connector 21, and control circuitry 200.

The light sources 13a to 13d are disposed in the control board on the base 11. The light sources 13a, the light sources 13b, the light sources 13c, and the light sources 13d emit light of different wavelengths (i.e., different colors). The four light sources 13a are light sources each of which emits light of the same wavelength, and are arranged side by side. The four light sources 13b are light sources each of which emits light of the same wavelength, and are arranged side by side. The four light sources 13c are light sources each of which emits light of the same wavelength, and are arranged side by side. The four light sources 13d are light sources each of which emits light of the same wavelength, and are arranged side by side.

Four light sources 13 each of which emits light of the same wavelength are arranged side by side, for each wavelength. Thus, an amount of light of each wavelength can be increased, thereby enabling an optical emission spectrometer 100 to easily receive light through a window provided in a reference apparatus or a correction apparatus. However, the number of light sources 13 for each wavelength is not limited to four, and may be any number that is two or more. For a plurality of light sources per some wavelengths, the light sources 13a, the light sources 13b, the light sources 13c, and the light sources 13d, are spaced apart from each other. Further, for the light sources 13a, the light sources 13b, the light sources 13c, and the light sources 13d, the number of light sources for the same wavelength is not limited to two or more, and may be one when an amount of light emitted from a single light source is sufficient. In this case, one light source 13a, one light source 13b, one light source 13c, and one light source 13d may be arranged side by side.

The light sources 13a to 13d are preferably positioned along the outermost perimeter of the base 11. In such a manner, a given optical emission spectrometer 100 more easily receives light emitted from the light sources 13a to 13d. However, the arrangement of the light sources 13a to 13d is not particularly restricted when such light sources are in the control board 12.

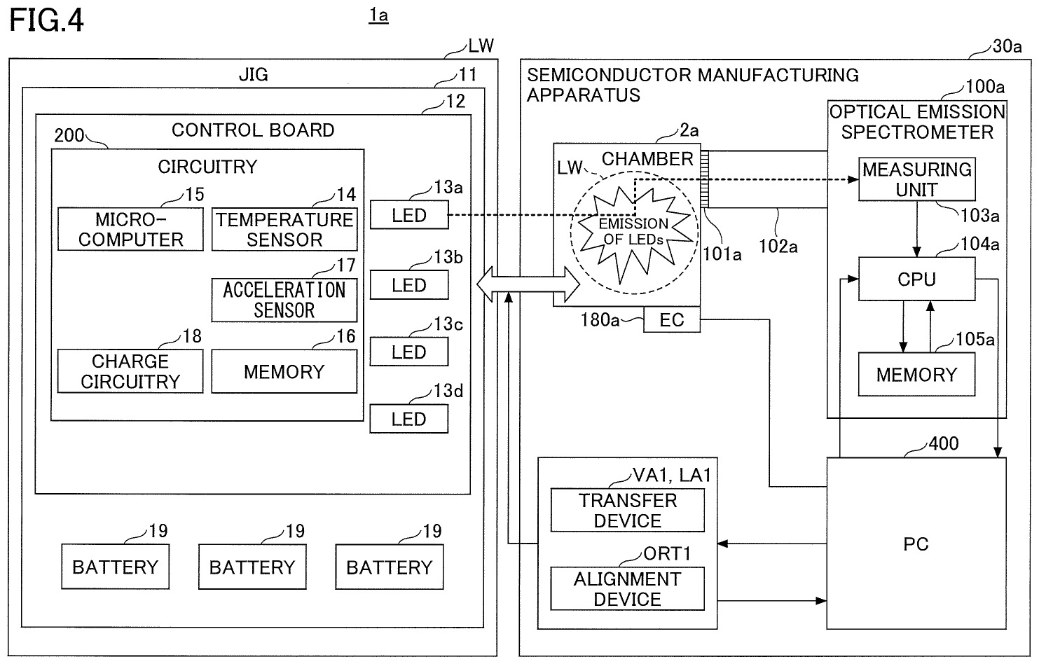

Each of the light sources 13a to 13d is preferably a light emitting diode (LED) or an organic light emitting diode (OLE) (see FIG. 4).

In the jig LW according to the embodiment, when the LED or the OLED is used as each of the light sources 13a to 13d, an amount of light emitted from the light source can be prevented from being reduced over time. Also, accuracy of analysis by the optical emission spectrometer 100 can be prevented from being decreased. Further, by use of the LED or the OLED, the jig LW can be reduced in size.

The plurality of light sources 13a to 13d preferably have a wavelength range of from 200 nm to 850 nm. The light emitted from each of the light sources 13a to 13d is not limited to visible light, and may be ultraviolet or infrared. Note that each light source 13 may emit light having various wavelengths (colors), by using a white LED, for example.

Each of the light sources 13a to 13d is rotated and transferred to a location approaching the window of the chamber to which a given optical emission spectrometer 100 is attached. In this case, the optical emission spectrometer 100 easily receives light from each light source. Note that a notch 22 is formed at an edge of the base 11, and the notch is configured to enable the rotation of the jig LW, which is transferred by the alignment device described below, to be controlled.

Each of temperature sensors 14a to 14d is disposed proximal to given light sources from among the light sources 13a to 13d, and each temperature sensor corresponds to the given light sources. The temperature sensor 14a measures an ambient temperature of the light sources 13a. The temperature sensor 14b measures an ambient temperature of the light sources 13b. The temperature sensor 14c measures an ambient temperature of the light sources 13c. The temperature sensor 14d measures an ambient temperature of the light sources 13d.

The control circuitry 200 is disposed in the control board 12 on the base 11, and includes a microcomputer 15, a memory 16, charge circuitry 18, and the like. The control circuitry 200 turns on or off each of the light sources 13a to 13d based on a given program. The control circuitry 200 serves as a controller that controls each component of the jig LW. The control circuitry 200 controls turning on and off of each of the light sources 13a to 13d, for example. The control circuitry 200 may control communication with other devices.

The connector 21 is a connector that connects with an external power source and is used to charge one or more batteries. Four batteries 19 are disposed on the base 11. Each battery 19 supplies power to light sources 13a to 13d and the control circuitry 200. Each battery 19 is an example of a power source that supplies power to a plurality of light sources and a controller. The number of batteries 19 is not limited to four as long as one or more batteries can support the maximum current of the light sources 13a to 13d.

An acceleration sensor 17 is provided in the jig LW. The acceleration sensor 17 detects the inclination of the jig LW, as well as transfer movement of the jig LW in a given apparatus.

### Plasma Processing Apparatus

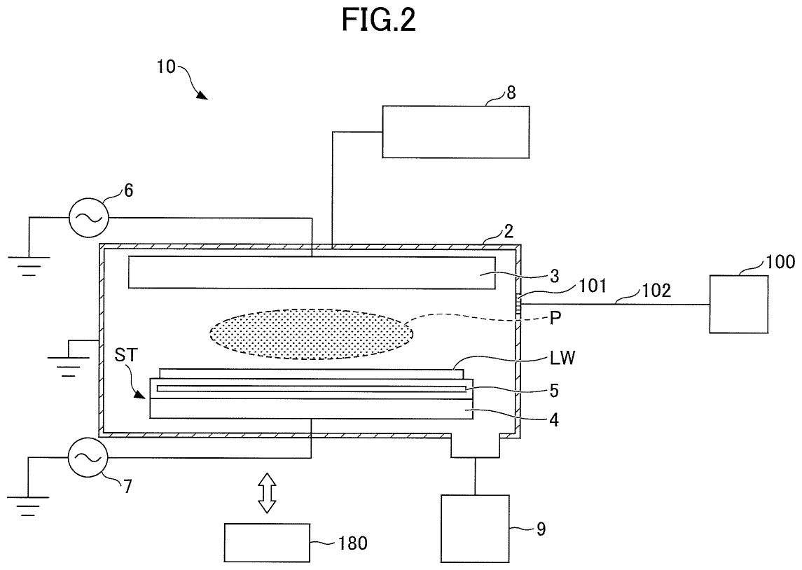

In such a configuration, the jig LW can be transferred to a plasma processing apparatus that performs substrate processing, such as etching, or deposition. FIG. 2 is a diagram illustrating an example of the plasma processing apparatus 10 according to the embodiment. The plasma processing apparatus 10 is used in an example of some plasma formation systems that is used to excite a plasma from a process gas.

In FIG. 2, the plasma processing apparatus 10 is a capacitively coupled plasma (CCP) apparatus, and a plasma P is formed between an upper electrode 3 and a stage ST, in a chamber 2. The stage ST includes a lower electrode 4 and an electrostatic chuck 5. During the process, a substrate is held on the lower electrode 4. A window 101 through which light is transmissive is provided in the chamber 2, and the optical emission spectrometer 100 is connected to the window 101 via an optical fiber 102. When emission intensity of the plasma is analyzed using the optical emission spectrometer 100, the substrate is held on the lower electrode 4. A radio frequency (RF) source 6 is coupled to the upper electrode 3, and a radio frequency (RF) source 7 is coupled to the lower electrode 4. The RF source 6 and the RF source 7 may be set at different radio frequencies. In another example, the RF source 6 and the RF source 7 may be coupled to the same electrode. A direct current (DC) power source may be coupled to the upper electrode. A gas source 8 is connected to the chamber 2 to supply a process gas. An exhauster 9 is also connected to the chamber 2 to evacuate the interior of the chamber 2.

The plasma processing apparatus 10 in FIG. 2 includes an equipment controller (EC) 180 including a processor and a memory. The plasma processing apparatus 10 controls each component of the plasma processing apparatus to process the substrate with the plasma.

### Semiconductor Manufacturing Apparatus

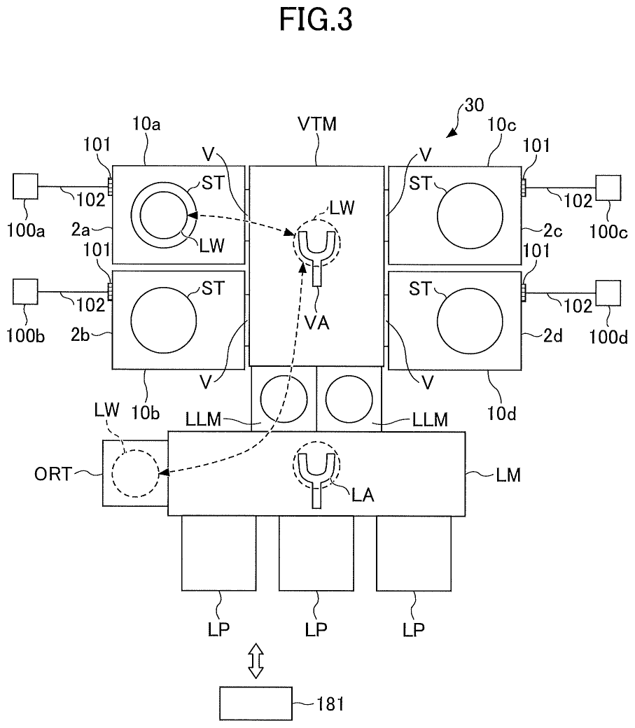

Hereafter, a semiconductor manufacturing apparatus 30 with plasma processing apparatuses 10 will be described with reference to FIG. 3. FIG. 3 is a diagram illustrating an example of the semiconductor manufacturing apparatus 30 according to the embodiment. The semiconductor manufacturing apparatus 30 includes four plasma processing apparatuses 10 each of which has the configuration in FIG. 2. The respective plasma processing apparatuses 10 are indicated as plasma processing apparatus 10a to 10d.

The semiconductor manufacturing apparatus 30 includes chambers 2a to 2d (which are also collectively referred to as “chambers 2”), which are provided in the respective plasma processing apparatuses 10a to 10d. The semiconductor manufacturing apparatus 30 also includes a vacuum transfer module VTM, two load lock modules LLM, a loader module LM, and an alignment device ORT. The semiconductor manufacturing apparatus 30 further includes three load ports LP, and a machine controller (MC) 181.

On each side of opposing sides of the vacuum transfer module VTM, two chambers from among the chambers 2a to 2d are arranged side by side, along the corresponding side of the vacuum transfer module VTM. In each of the chambers 2a to 2d, predetermined processing is performed for a given substrate. Each gate valve V is openable and closable connected to between a given chamber from among the chambers 2a to 2d, and the vacuum transfer module VTM. The interior of each of the chambers 2a to 2d is depressurized to be in a vacuum atmosphere.

A transfer device VA for transferring the substrate is disposed in an interior of the vacuum transfer module VTM. While holding the substrate on a pick at an arm tip, the transfer device VA can deliver the substrate between each of the chambers 2a to 2d, and a given load lock module LLM. The transfer device VA can hold the jig LW on the arm pick and deliver the jig LW between each of the chambers 2a to 2d and a given load lock module LLM.

Each load lock module LLM is provided between the vacuum transfer module VTM and the loader module LM. The atmosphere of each load lock module LLM is switched between an air atmosphere and a vacuum atmosphere. The substrate is transferred between an air space of the loader module LM and a vacuum space of the vacuum transfer module VTM.

The interior of the loader module LM is maintained clean by a downflow, and the three load ports LP are provided on a sidewall of the loader module LM. A front opening unified pod (FOUP) is attached to each load port LP, where the FOUP accommodates, e.g., 25 substrates or is empty. A given substrate is transferred from a given load port LP to a given chamber from among the chambers 2a to 2d. Further, after the substrate is processed, the processed substrate is transferred from a given chamber, from among the chambers 2a to 2d, to a given load port LP.

A transfer device LA that transfers the substrate is disposed in an interior of the loader module LM. While holding the substrate on a pick at an arm tip, the transfer device LA can deliver the substrate between a given FOUP and a given load lock module LLM. While holding the jig LW on the pick at the arm tip, the transfer device LA can deliver the jig LW between a given chamber from among the chambers 2a to 2d, and a given load lock module LLM.

The alignment device ORT, which adjusts a position of a given substrate, is provided on the loader module LM. The alignment device ORT is disposed on one end of the loader module LM, for example. The alignment device ORT detects a center position, eccentricity, and a notch position of the substrate. The transfer device LA, which is disposed in the loader module LM, adjusts the position of the substrate, based on a detected result at the alignment device ORT. The alignment device ORT detects a center position, eccentricity, and a notch position of the jig LW. The transfer device LA, which is disposed in the loader module LM, adjusts the position of the jig LW, based on a detected result at the alignment device ORT.

Note that the number of chambers 2a to 2d, the number of load lock modules LLM, the number of loader modules LM, and the number of load ports LP are not limited to the numbers described in the embodiment, and any number may be adopted. The jig LW can be transferred in the same manner as the substrate. The jig LW has the shape enabling each of the transfer devices LA and VA to transfer the jig LW, where the transfer device VA is provided in the vacuum transfer module VTM. In such a manner, the jig LW can be transferred between a given plasma processing apparatus 10, which is an example of a given apparatus, and the vacuum transfer module VTM, without breaking the vacuum.

The MC 181 includes a central processing unit (CPU), a read only memory (ROM), a random access memory (RAM), and a hard disk drive (HDD). Note that the MC 181 may have another storage area in a solid state drive (SDD) or the like.

The CPU controls a substrate process in each of the chambers 2a to 2d, in accordance with a recipe in which a process procedure and a process condition are set. The recipe is stored in a storage that includes the ROM, the RAM, or the HDD. A program, which is executed to control the process and transfer of a given substrate, is stored in the storage. A program that is executed to control a transfer process for the jig LW is stored in the storage. The CPU controls the transfer of the jig LW in accordance with a program in which a transfer procedure and condition of the jig LW is set.

The optical emission spectrometers 100a to 100d (which are collectively referred to as “optical emission spectrometers 100”) are respectively attached, through optical fibers 102, to windows 101 provided in the chambers 2a to 2d. Each window 101 transmits light. When the jig LW is mounted on a given stage ST and the light sources 13 provided in the jig LW are turned on, a given optical emission spectrometer 100 receives light emitted through a given window 101.

In the semiconductor manufacturing apparatus, the jig LW may be disposed in a given FOUP or in the alignment device ORT. A given alignment device is disposed in a space in a transfer system such as the vacuum transfer module VTM, and the jig LW may be disposed in such an alignment device. When an amount of light emitted from the light sources 13a to 13d in the jig LW is sufficient for a given optical emission spectrometer 100 to perform analysis, analysis may be performed based on light emitted from the light sources 13a to 13d, without rotating the jig LW. In this case, the alignment device ORT may not be used.

An example of the analysis at the optical emission spectrometer 100 includes a process monitor such as end point detection (EPD). When a given window becomes cloudy due to adherence or the like of a reaction product generated in the substrate processing, sensitivity of the optical emission spectrometer 100 is decreased. The sensitivity of the optical emission spectrometer 100 varies depending on a state in which a given optical fiber 102 connecting the chamber and the optical emission spectrometer 100 is drawn.

For the jig LW according to the embodiment, each optical emission spectrometer 100 can receive light in a state in which the light sources 13 are in the interior of a given chamber 2. Without opening a cover of the chamber 2 to thereby become open to the atmosphere, the jig LW can be transferred to a given chamber 2 while the interior of the chamber 2 is maintained as a vacuum. Thus, sensitivity of the optical emission spectrometer 100 can be adjusted to an optimum value, and intensity of an emission signal can be stabilized.

In the embodiment, each window 101 has a double-window configuration in which each window has a honeycomb structure. In such a manner, plasmas and radicals are prevented from entering the window 101, and an amount of the reaction product that adheres to the window 101 can be reduced as much as possible. Accordingly, intensity of light received at each optical emission spectrometer 100 can be prevented from being reduced.

Note that when a given plasma processing apparatus, from among the plasma processing apparatuses 10a to 10d, processes a given substrate is a given chamber 2, the jig LW is mounted on the stage ST in a different chamber 2 from the given plasma processing apparatus, and then a given optical emission spectrometer 100 may receive light through the different chamber 2.

### Processing System

Hereafter, a processing system 1a when acquiring reference data indicating emission intensity will be described with reference to FIG. 4. FIG. 4 is a diagram illustrating an example of a hardware configuration of the processing system la including a semiconductor manufacturing apparatus 30a according to the embodiment. The processing system 1a includes the semiconductor manufacturing apparatus 30a and the jig LW. The semiconductor manufacturing apparatus 30a includes the chamber 2a, the optical emission spectrometer 100a, a personal computer (PC) 400, transfer devices VA1 and LA1, and an alignment apparatus ORT1.

The optical emission spectrometer 100a includes a measuring unit 103a, a CPU 104a, and a memory 105a. The measuring unit 103a measures data indicating emission intensity from light emitted from the light sources 13 in the jig LW. The memory 105a stores a given program for analyzing data indicating emission intensity from light emitted from the light sources 13 that are provided in the jig LW. The CPU 104a executes the program stored in the memory 105a to measure light emitted from the light sources 13 in the jig LW, which is transferred to the chamber 2a in a reference plasma processing apparatus 10. The CPU 104a also analyzes data indicating emission intensity. Data indicating measured emission intensity is stored in the memory 105a, as reference data.

The PC 400 performs a control to cause the jig LW to be transferred between the chamber 2a of the reference plasma processing apparatus 10 and the vacuum transfer module VTM, while maintaining a reduced pressure environment of the chamber 2a (process chamber). The PC 400 also causes the jig LW to be transferred to the alignment device ORT1 and causes the notch 22 to be rotated in a direction specified as a reference. Further, the PC 400 causes a rotated jig LW to be mounted on the stage ST. The jig LW turns on the light sources 13a at locations approaching the window 101a of the chamber 2a. The measuring unit 103a receives light of a first wavelength that is emitted from the light sources 13a, through the window 101a. The CPU 104a analyzes emission intensity of the received light of the first wavelength.

Then, the PC 400 again causes the jig LW to be transferred to the alignment device ORT1 and causes the notch 22 to be rotated in the direction specified as a reference. The PC 400 causes a rotated jig LW to be mounted on the stage ST. The jig LW turns on the light sources 13b at locations approaching the window 101a of the chamber 2a. The measuring unit 103a receives light of a second wavelength that is emitted from the light sources 13b, through the window 101a. The CPU 104a analyzes emission intensity of the received light of the second wavelength.

Then, the PC 400 again causes the jig LW to be transferred to the alignment device ORT1 and causes the notch 22 to be rotated in the direction specified as a reference. The PC 400 causes a rotated jig LW to be mounted on the stage ST. The jig LW turns on the light sources 13c at locations approaching the window 101a of the chamber 2a. The measuring unit 103a receives light of a third wavelength that is emitted from the light sources 13b, through the window 101a. The CPU 104a analyzes emission intensity of the received light of the third wavelength.

Then, the PC 400 again causes the jig LW to be transferred to the alignment device ORT1 and causes the notch 22 to be rotated in the direction specified as a reference. The PC 400 causes a rotated jig LW to be mounted on the stage ST. The jig LW turns on the light sources 13d at locations approaching the window 101a of the chamber 2a. The measuring unit 103a receives light of a fourth wavelength that is emitted from the light sources 13c, through the window 101a. The CPU 104a analyzes emission intensity of the received light of the fourth wavelength.

Note that for light of the first wavelength from the light source 13a, light of the fourth wavelength from the light source 13d, light of the third wavelength from the light source 13c, and light of the second wavelength from the light source 13b, if the condition “the first wavelength<the fourth wavelength<the third wavelength<the second wavelength” is satisfied, measurement is preferably performed in a clockwise direction. For example, the measuring unit 103a preferably measures light of respective wavelengths in order of the light sources 13a that emit light of the first wavelength, the light sources 13d that emit light of the fourth wavelength, the light sources 13c that emit light of the third wavelength, and the light sources 13b that emit light of the second wavelength. By sequentially measuring light from given light sources 13 that are next to each other, a rotation amount of the jig LW that rotates through the alignment device ORT1 can be reduced.

The CPU 104a combines data indicating emission intensity from light of the first to fourth wavelengths, and stores, as reference data, combination data of the data indicating the emission intensity, in the memory 105a.

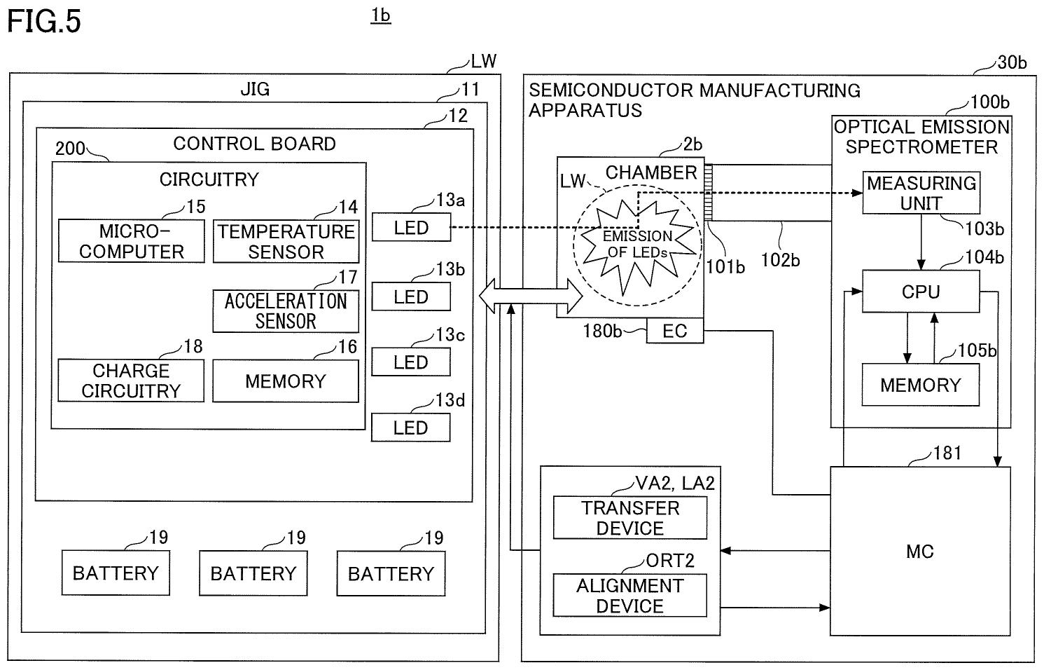

Hereafter, a processing system 1b used when measurement data indicting emission intensity is compared with the reference data to thereby be corrected will be described with reference to FIG. 5. FIG. 5 is a diagram illustrating an example of a hardware configuration of the processing system 1b including a semiconductor manufacturing apparatus 30b according to the embodiment. The processing system 1b includes the semiconductor manufacturing apparatus 30b and the jig LW. The semiconductor manufacturing apparatus 30b includes the chamber 2b, the optical emission spectrometer 100b, the MC 181, transfer devices VA2 and LA2, and an alignment apparatus ORT2.

The optical emission spectrometer 100b includes a measuring unit 103b, a CPU 104b, and a memory 105b. The measuring unit 103b measures data indicating emission intensity from light that is emitted from the light sources 13 provided in the jig LW. The memory 105b stores a given program for analyzing data indicating emission intensity from light that is emitted from the light sources 13 in the jig LW. The CPU 104b executes the program stored in the memory 105b to measure light that is emitted from the light sources 13 in the jig LW that is transferred to the chamber 2b in a correction plasma processing apparatus 10. The CPU 104b also analyzes data indicating emission intensity. The CPU 104b compares measurement data indicating measured emission intensity with the reference data stored in the memory 105a. The CPU 104b corrects the measurement data based on a compared result.

The MC 181 performs a control to cause the jig LW to be transferred between the chamber 2b of the reference plasma processing apparatus 10 and the vacuum transfer module VTM, while maintaining a reduced pressure environment of the chamber 2b (process chamber). The MC 181 also causes the jig LW to be transferred to the alignment device ORT2 and causes the notch 22 to be rotated in a direction specified as a reference. Further, the MC 181 causes a rotated jig LW to be mounted on the stage ST. The jig LW turns on the light sources 13a at locations approaching the window 101b of the chamber 2b. The measuring unit 103b receives light of a first wavelength that is emitted from the light sources 13a, through the window 101b. The CPU 104b analyzes emission intensity of the received light of the first wavelength.

Then, the MC 181 again causes the jig LW to be transferred to the alignment device ORT2 and causes the notch 22 to be rotated in the direction specified as a reference. The MC 181 causes a rotated jig LW to be mounted on the stage ST. The jig LW turns on the light sources 13b at locations approaching the window 101b of the chamber 2b. The measuring unit 103b receives light of a second wavelength that is emitted from the light sources 13b, through the window 101b. The CPU 104b analyzes emission intensity of the received light of the second wavelength.

Then, the MC 181 again causes the jig LW to be transferred to the alignment device ORT2 and causes the notch 22 to be rotated in the direction specified as a reference. The MC 181 causes a rotated jig LW to be mounted on the stage ST. The jig LW turns on the light sources 13c at locations approaching the window 101b of the chamber 2b. The measuring unit 103a receives light of a third wavelength that is emitted from the light sources 13b, through the window 101b. The CPU 104b analyzes emission intensity of the received light of the third wavelength.

Then, the MC 181 again causes the jig LW to be transferred to the alignment device ORT2 and causes the notch 22 to be rotated in the direction specified as a reference. The PC 400 causes a rotated jig LW to be mounted on the stage ST. The jig LW turns on the light sources 13d at locations approaching the window 101b of the chamber 2b. The measuring unit 103b receives light of a fourth wavelength that is emitted from the light sources 13c, through the window 101b. The CPU 104b analyzes emission intensity of the received light of the fourth wavelength.

The CPU 104b combines data indicating emission intensity from light of the first to fourth wavelengths. The CPU 104b also compares combination data of the data indicating the emission intensity, as measurement data, with the reference data stored in the memory 105a.

The CPU 104b corrects the measurement data indicating combined emission intensities, based on a compared result. In other words, the CPU 104b calculates a difference between the measurement data indicating the combined emission intensities and the reference data, and corrects the measurement data indicating the combined emission intensities so that the measurement data indicates the same waveform as the reference data.

A server acquires, from the optical emission spectrometer 100b, data (hereinafter referred to as “correction data”) indicating corrected emission intensity, and then stores the correction data. In such a manner, a state of a given plasma processing apparatus 10, and differences according to each plasma processing apparatus 10 can be analyzed based on log data of accumulated correction data. The server may be a host computer that is connected to a plurality of MCs 181 for controlling respective semiconductor manufacturing apparatuses 30 and that collects correction data from each of the MCs 181.

### Operation of Processing System

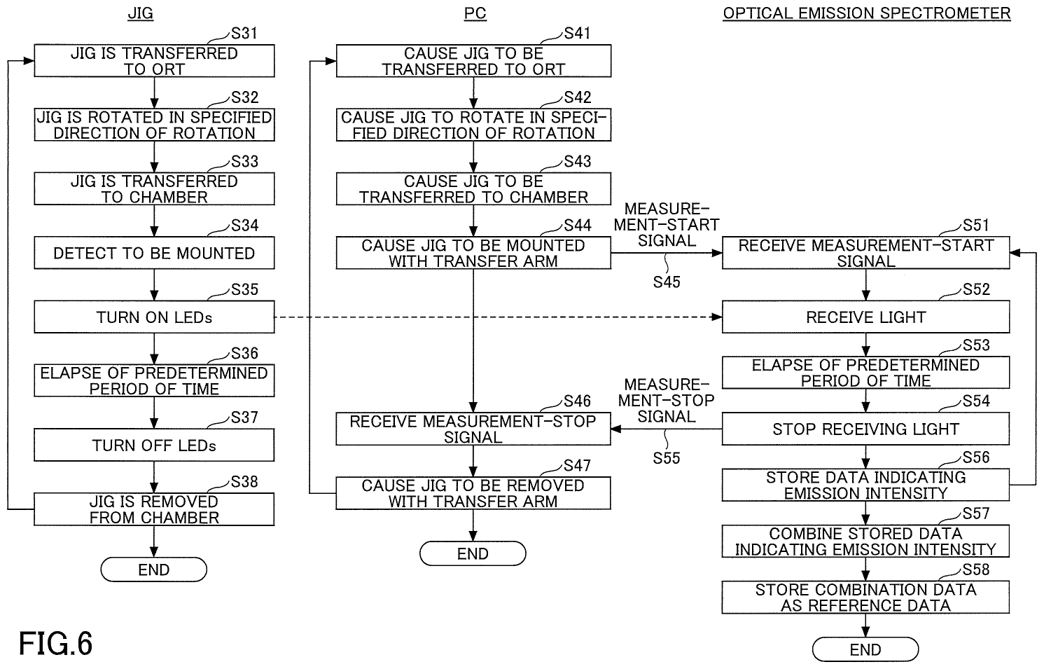

Hereafter, an example of the operation of the processing system 1a used when the reference data according to the embodiment is obtained will be described with reference to FIG. 6. FIG. 6 is a diagram illustrating an example of the operation of the processing system 1a according to the embodiment. A left-side line in FIG. 6 relates to a process of the jig LW. A middle-portion line in FIG. 6 relates to a process of the PC 400. A right-side line in FIG. 6 relates to a process of the optical emission spectrometer 100a.

When the process is initiated, the PC 400 causes the jig LW to be transferred to the alignment device ORT1 using the transfer devices VA1 and LA1 (steps S31 and S41). Then, the PC 400 causes the jig LW to rotate in a specified direction of rotation in the alignment device ORT1 (steps S32 and S42). Then, the PC 400 causes the jig LW to be transferred to the chamber 2a of the reference plasma processing apparatus 10, using the transfer devices VA1 and LA1 (steps S33 and S43).

Then, the PC 400 causes the jig LW to be mounted on the stage ST in the chamber 2a, through a pick operation of the transfer device VA1 (step S44). At this time, the PC 400 transmits a measurement-start signal to the optical emission spectrometer 100a (step S45). The optical emission spectrometer 100a receives the measurement-start signal (step S51).

At the timing at which the process in step S44 is performed, the jig LW detects that it is to be mounted (step S34). The jig LW detects that it is to be mounted on the stage ST, through a given temperature sensor 14 or the acceleration sensor 17. The acceleration sensor 17 detects the inclination of the jig LW and a lifting operation of the jig LW. The temperature sensor 14 detects the temperature of the stage ST. The jig LW detects at least one from among the inclination, lifting operation, and temperature of the jig LW, to determine whether to be mounted on the stage ST. At a timing at which the jig detects that is to be mounted, the jig LW turns on the LED light sources 13a (step S35). The optical emission spectrometer 100a receives LED light (step S52).

After a predetermined period of time has elapsed since the light sources 13a are turned on (step S36), the jig LW turns off the LED light sources 13a (step S37). After a predetermined period of time has elapsed since the light sources 13a are turned on (step S53), the optical emission spectrometer 100a stops receiving the LED light (step S54). For a result of optical emission spectroscopy in a target wavelength range (which is the first wavelength, for example), the optical emission spectrometer 100a stores data indicating emission intensity, in the memory 105a (step S56). In such a manner, the data indicating the emission intensity at the first wavelength is stored in the memory 105a.

In step S54, the optical emission spectrometer 100a stops receiving the LED light, and then transmits a measurement-stop signal to the PC 400 (step S55). When the PC 400 receives the measurement-stop signal (step S46), the PC 400 causes the jig LW to be removed from the chamber 2a, through the pick operation of the transfer device VA1 (step S47). Thus, the jig LW is removed from the chamber 2a (step S38).

The PC 400 repeats the process in steps S41 to S47, the jig LW repeats the process in steps S31 to S38, and the optical emission spectrometer 100a repeats the process in steps S51 to S56. In such a manner, the optical emission spectrometer 100a measures light sequentially emitted from the light sources 13b, the light sources 13c, and the light sources 13d, and performs spectroscopic analysis in sequence. For a result of optical emission spectroscopy in a target wavelength range (which is the second wavelength, third wavelength, or fourth wavelength, for example), the optical emission spectrometer 100a stores each data indicating emission intensity at a given target wavelength, in the memory 105a (step S56). In such a manner, in addition to the data indicating the emission intensity at the first wavelength, respective pieces of data indicating the emission intensity at the second wavelength, the third wavelength, and the fourth wavelength are stored in the memory 105a.

The PC 400 repeats the process in steps S41 to S47 a predetermined number of times (in this example, 4 times), and then terminates the process.

The jig LW repeats the process in steps S31 to S38 a predetermined number of times (in this example, 4 times), and then terminates the process. The optical emission spectrometer 100a repeats the process in steps S51 to S56 a predetermined number of times (in this example, 4 times). Then, the optical emission spectrometer 100a combines the stored data indicating emission intensity (step S57).

Then, the optical emission spectrometer 100a stores, as reference data, combination data of measurement data indicating emission intensity, in the memory 105a (step S58). The process is terminated.

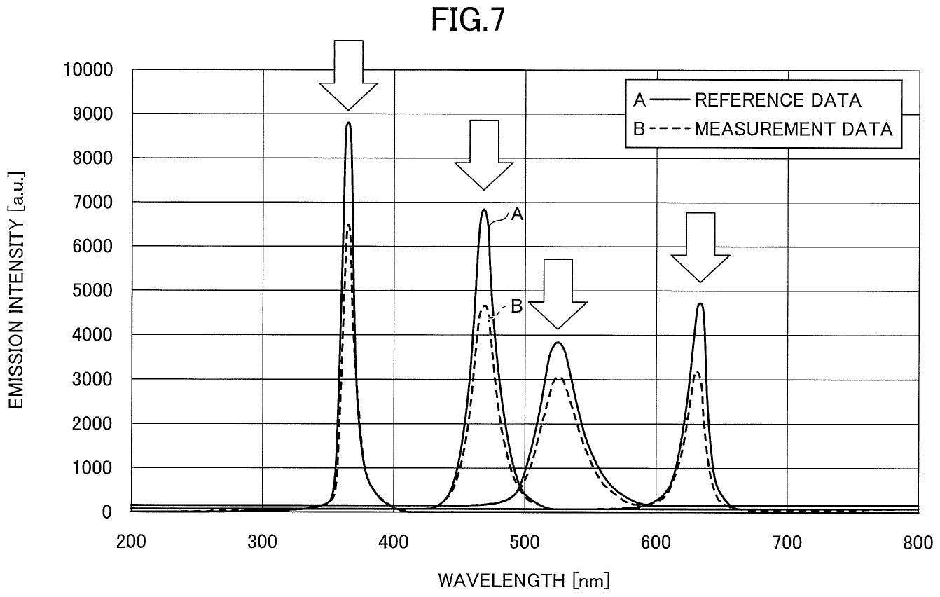

FIG. 7 is a diagram illustrating an example of the reference data according to the embodiment. FIG. 7 illustrates data indicating emission intensity with four peaks at respective different wavelengths, where the data is used as an example of reference data A indicating emission intensity according to the embodiment.

Note that the predetermined period of time in step S36 corresponds to the predetermined period of time in step S53. Instead of the process in step S36 and step S53, the following process may be performed. The PC 400 determines whether the jig LW moves away from the stage ST through a pick operation of the transfer device VA1. If it is determined that the jig LW moves away from the stage ST, the PC 400 transmits a measurement-stop signal to the jig LW and the optical emission spectrometer 100a. In response to receiving the measurement-stop signal, the jig LW turns off the LED light sources 13a. The optical emission spectrometer 100a stops receiving LED light in response to receiving the measurement-stop signal. The jig LW may detect to move away from the stage ST, through a given temperature sensor 14 or the acceleration sensor 17.

In the embodiment, the jig LW, the PC 400, and the optical emission spectrometer 100a may perform wireless communication to perform the process in the steps illustrated in FIG. 6.

### Operation of Optical Emission Spectrometer

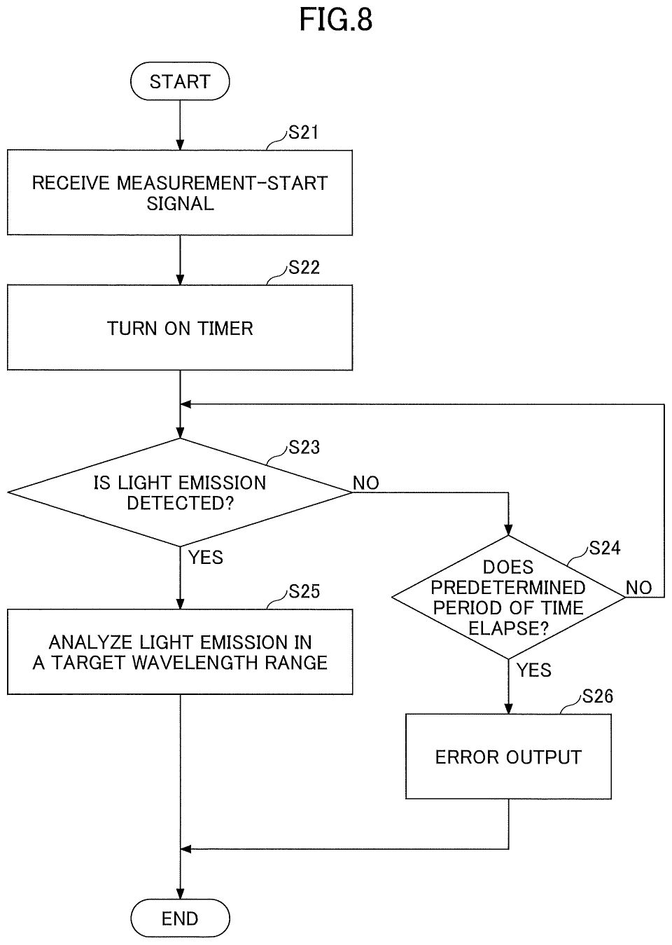

Hereafter, an example of the operation of the optical emission spectrometer 100a according to the embodiment will be described with reference to FIG. 8. FIG. 8 is a diagram illustrating an example of the operation of the optical emission spectrometer 100a according to the embodiment.

When the process is initiated, the optical emission spectrometer 100a receives the measurement-start signal (see step S45 in FIG. 6) transmitted by the PC 400 (step S21). Then, the optical emission spectrometer 100a turns on a timer (step S22). Then, the optical emission spectrometer 100a determines whether light emission is detected through the window 101a of the chamber 2a (step S23). If it is determined that light emission is not detected, the optical emission spectrometer 100a determines whether a set time has elapsed based on a time period measured by the timer (step S24). If it is determined that a set time does not elapse, the optical emission spectrometer 100a returns to step 23 to determine whether light emission is detected. If light emission is detected before the set time elapses, the optical emission spectrometer 100a analyzes light emission in a target wavelength range (step S25) and then terminates the process. In contrast, if a set time elapses without detecting light emission, the optical emission spectrometer 100a outputs an error signal (step S26) and then terminates the process. Note that data indicating emission intensity that is obtained in an analyzed result is stored in the memory 105a, as reference data (see step S56 in FIG. 6).

### Operation of Processing System

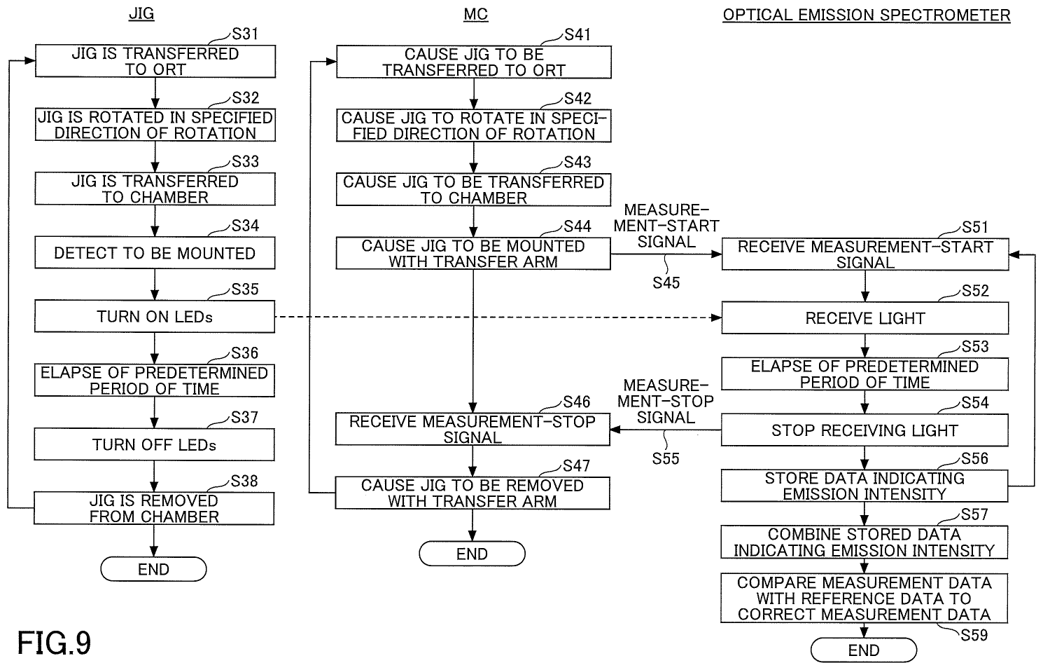

Hereafter, an example of the operation of the processing system 1b used when the reference data according to the embodiment is compared with the measurement data and the measurement data is corrected will be described with reference to FIG. 9. FIG. 9 is a diagram illustrating an example of the operation of the processing system 1b according to the embodiment. A left-side line in FIG. 9 relates to the process of the jig LW. A middle-portion line in FIG. 9 relates to the process of the MC 181. A right-side line in FIG. 9 relates to the process of the optical emission spectrometer 100b.

The operation of the jig LW in FIG. 9 is the same as the operation of the jig LW in FIG. 6, and the same processes denote the same step numerals. The operation of the MC 181 in FIG. 9 is the same as the operation of the PC 400 in FIG. 6, and the same processes denote the same step numerals. The operation of the optical emission spectrometer 100b in FIG. 9 is approximately the same as the operation of the optical emission spectrometer 100a in FIG. 6, and the same processes denote the same step numerals. For differences between the processing system 1b in FIG. 9 and the processing system 1a in FIG. 6, first, in the processing system 1b in FIG. 9, the optical emission spectrometer 100b performs the process in step S59, while in the processing system la in FIG. 6, the optical emission spectrometer 100a performs the process in step S58. Further, in step S44 in FIG. 9, a given chamber 2 to which the jig LW is transferred is the chamber 2b of the correction plasma processing apparatus 10, while in step S33 in FIG. 6, a given chamber 2 to which the jig LW is transferred is the chamber 2a of the reference plasma processing apparatus 10. The description for the same process as the processing system 1a in FIG. 6, other than the above differences, will be omitted as a whole.

When the process is initiated, the MC 181 repeats the process in steps S41 to S47, the jig LW repeats the process in steps S31 to S38, and the optical emission spectrometer 100b repeats the process in steps S51 to S56. In such a manner, the optical emission spectrometer 100b measures light sequentially emitted from the light sources 13b, the light sources 13c, and the light sources 13d, and performs spectroscopic analysis in sequence. For a result of optical emission spectroscopy in a target wavelength range (which is the second wavelength, third wavelength, or fourth wavelength, for example), the optical emission spectrometer 100b stores each data indicating emission intensity at a given target wavelength, in the memory 105b. In such a manner, measurement data, indicating emission intensities at the first to fourth wavelengths in the chamber 2b of the correction plasma processing apparatus 10, are stored in the memory 105b.

The MC 181 repeats the process in steps S41 to S47 a predetermined number of times (in this example, 4 times), and then terminates the process. The jig LW repeats the process in steps S31 to S38 a predetermined number of times (in this example, 4 times), and then terminates the process. The optical emission spectrometer 100b repeats the process in steps S51 to S56 a predetermined number of times (in this example, 4 times). Then, the optical emission spectrometer 100b combines the stored data indicating emission intensity (step S57).

Then, the optical emission spectrometer 100b compares combination data of the data indicating emission intensity at the first to fourth wavelengths, as measurement data, with the reference data, and corrects the measurement data so as to match the reference data (step S59). The process is then terminated. A dotted line in FIG. 7 represents an example of measurement data B according to the embodiment. The optical emission spectrometer 100b calculates a difference between the reference data A and the measurement data B, and corrects the measurement data B so that the measurement data B has the same waveform as the reference data A. In such a manner, by correcting of peak positions and emission intensities for the measurement data B, the measurement data B can be corrected to have the same waveform as the reference data A.

Note that in the embodiment, the jig LW, the MC 181, and the optical emission spectrometer 100b may perform wireless communication to perform the process in the steps illustrated in FIG. 9.

### Operation of Optical Emission Spectrometer

The operation of the optical emission spectrometer 100a in FIG. 8 is performed in conjunction with the operation of the PC 400 in FIG. 6. Likewise, the operation of the optical emission spectrometer 100b is performed in conjunction with the operation of the MC 181 in FIG. 9. Note that the operation of the optical emission spectrometer 100b is the same as that of the optical emission spectrometer 100a illustrated in FIG. 8, and the description for the operation of the optical emission spectrometer 100b will be omitted.

The LED light sources 13 have individual differences. For this reason, preferably, the reference data is preliminarily measured and stored in the memory 105a. The reference data may be generated using an information processing apparatus on a jig manufacturer side such as a jig manufacturing factory. However, such a manner is not limiting. The reference data may be generated using an information processing apparatus on a manufacturer side of the semiconductor manufacturing apparatus 30a, or may be generated using an information processing apparatus on a user side such as a factory to which the semiconductor manufacturing apparatus 30a is shipped. Further, reference data may be generated individually for each jig LW, or alternatively, reference data in common with multiple jigs LW may be generated.

As described above, in a given processing system 1 according to one or more embodiments and modifications, a given optical emission spectrometer 100 calculates the difference between the measurement data indicating combined emission intensities and the reference data, and corrects one or more peaks and emission intensities of the measurement data, so that the measurement data has the same waveform as the reference data. In such a manner, monitoring and controlling of the process, such as EPD, can be performed in consideration of differences according to each plasma processing apparatus 10.

In other words, by correcting the measurement data indicating the emission intensities so that the measurement data has the same waveform as the reference data, when light of the same wavelength is received, even in a case where LED light is thereby received from a given chamber 2 at any timing, measurement data indicating the same emission intensity is obtained. In such a manner, monitoring and controlling of the process, such as EPD, can be performed in consideration of differences according to each plasma processing apparatus 10.

Further, in such a manner, differences according to each plasma processing apparatus 10 can be detected based on the measurement data indicating emission intensity. In other words, the differences according to each plasma processing apparatus 10 can be identified from the difference between the measurement data indicating emission intensity, and the reference data, and operation of the process monitor or the like can be performed in consideration of the identified differences according to each plasma processing apparatus 10.

The correction of the measurement data described above may be performed at a time of shipment, or may be performed at a timing at which a given window 101 becomes cloudy due to a reaction product or the like that adheres to the window 101 in accordance with a substrate process. Alternatively, such correction of the measurement data may be performed at regular intervals, or may be performed for each measurement data.

The operation of each component described above is not limiting. For example, for the operation of the MC 181, the ECC 180 may be performed instead of the MC 181, or be performed in cooperation with the MC 181.

A combination of the PC 400 and the optical emission spectrometer 100a is used as an example of a first information processing apparatus that performs a control to cause the jig LW to be disposed in a reference device and to measure, as reference data, data indicating emission intensity from light emitted from light sources 13. A combination of the MC 181 and the optical emission spectrometer 100b is used as an example of a second information processing apparatus that performs a control to cause the jig LW to be disposed in a correction device and to measure data indicating emission intensity from light emitted from light sources 13. The second information processing apparatus performs a control to acquire the reference data, compare data indicating measured emission intensity with the reference data, and correct the data (measurement data) indicating measured emission intensity, based on a compared result.

The first information processing apparatus may be the same information processing apparatus as the second information processing apparatus, or be a different information processing apparatus from the second information processing apparatus. For example, a combination of the MC 181 and the optical emission spectrometer 100b may have functions provided by both of the first information processing apparatus and the second information processing apparatus. A combination of the EC 180 and the optical emission spectrometer 100b may have functions provided by both of the first information processing apparatus and the second information processing apparatus. The functions provided by both of the first information processing apparatus and the second information processing apparatus may be implemented by a combination of the EC 180, the MC 181, and the optical emission spectrometer 100b that are in cooperation.

An instruction to transfer the jig LW to a given chamber may be sent at a timing at which a signal indicating that the substrate process is completed is received from the EC 180 that controls a given plasma processing apparatus 10.

The temperature sensors 14a to 14d that are provided in the jig LW are disposed next to the light sources 13a to 13d, respectively. When given light sources from among the light source 13a to 13d emit light, temperature of a corresponding temperature sensor from among the temperature sensors 14a to 14d increases. When a measured temperature is greater than or equal to a predetermined threshold, at least one light source from among light sources is determined to fail, and then emissions from the light sources may be interrupted.

Analysis by the optical emission spectrometers 100 (100a and 100b) is not limited to EPD, and may be used for device diagnosis. As an example of the device diagnosis, for example, it may be determined whether a plasma condition is normal based on a difference between measurement data indicating emission intensity and reference data, or on measurement data indicating emission intensity after correction. For example, such device diagnosis may be performed after maintenance of a given plasma processing apparatus 10, or after replacement of one or more component parts in a given plasma processing apparatus 10.

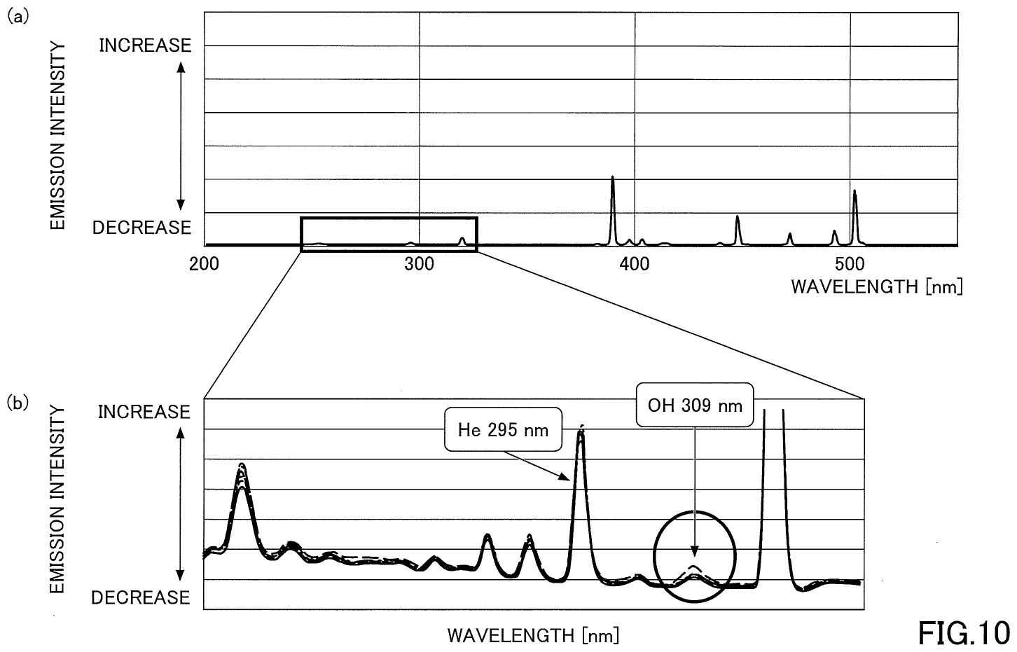

FIG. 10 is a diagram for describing an example of device diagnosis using a given processing system 1 according to the embodiment and modification. Given light sources 13 are turned on using the jig LW mounted in the plasma processing apparatus 10 in which a plasma is formed from a helium gas. Then, the optical emission spectrometer 100 performs spectroscopic analysis of the plasma from the helium gas to obtain emission intensity data illustrated in FIG. 10(a). FIG. 10(b) is an enlarged view of emission intensity distribution in a wavelength range of from 250 nm to 330 nm. In FIG. 10(b), a solid line represents reference data, and a dashed line represents measurement data after correction. In this case, for each of the reference data and the measured data, a peak for He (helium) appears at the wavelength of 295 nm. In contrast, for the measured data, a minor peak for OH radicals appears at the wavelength of 309 nm, compared with the reference data. From the result, the processing system 1 can determine that the minor peak for the OH radicals is caused by an uncertain factor of the chamber 2a. As described above, from the difference between the reference data and the measurement data, a minor peak that does not appear in a case of a theoretical light source that emits light approximating a plasma can be found, so that analysis can be performed. In such a manner, there is one or more important peaks used to analyze differences according to each plasma processing apparatus 10. Further, such differences according to each plasma processing apparatus 10 can be analyzed based on correction data indicating emission intensity. Thus, a given peak point is extracted and the measurement data can be corrected at the peak point.

As described above, the jig LW according to the embodiment can increase analytic accuracy of emission intensity. Further, by correcting the measurement data indicating emission intensity to thereby have the same waveform as the reference data, monitoring and controlling of the process, such as EPD can be performed in consideration of differences according to each plasma processing apparatus 10. Further, the differences according to each plasma processing apparatus 10 can be determined based on the measurement data indicating the emission intensity, and thus operation of the process monitor or the like can be performed taking into account the determined differences according to each plasma processing apparatus 10.

### Other Examples of Jig LW

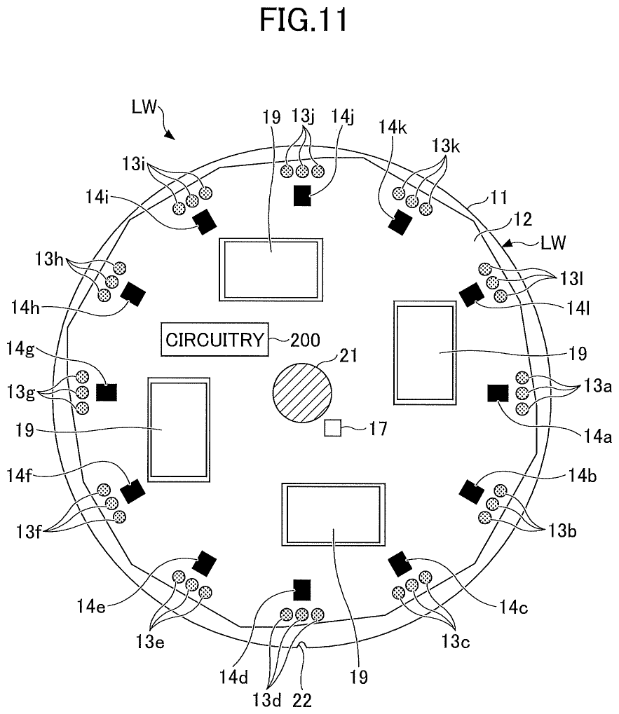

Other examples of the jig LW according to one embodiment will be described with reference to FIG. 11. FIG. 11 is a cross-sectional diagram illustrating another example of the jig LW according to the embodiment. The jig LW in FIG. 11 differs from the jig LW illustrated in FIG. 1, in the number and arrangement of light sources 13. Other configurations of the jig LW in FIG. 11 are the same as those of the jig LW illustrated in FIG. 1. The description for the same configurations will not be provided.

As illustrated in FIG. 11, light sources 13a to 13l are disposed in the control board 12 on the base 11. The light sources 13a to 13l emit light of respective different wavelengths (i.e., different colors). The light sources 13a are three LEDs each of which emits light of the same wavelength, and are arranged side by side. Likewise, the light sources 13b are three LEDs each of which emits light of the same wavelength and are arranged side by side. The light sources 13c are three LEDs each of which emits light of the same wavelength and are arranged side by side. Each of the light sources 13a to 13l may be an OLED instead of the LED.

With respect to the light sources 13a to 13l for respective wavelengths, three light sources each of which emits light of the same wavelength are arranged side by side, for each wavelength. In such a manner, an amount of light of each wavelength can be increased and thus the optical emission spectrometer 100 attached to a given window of a correction apparatus or a reference apparatus easily receives light of each wavelength through the window. The light sources 13a, the light sources 13b, and the light sources 13c are spaced apart. Following these light sources 13a, 13b, and 13c, the light sources 13d, the light sources 13e, and the light sources 13f are spaced apart in this order, relative to a given battery. Following these light sources 13d, 13e, and 13f, the light sources 13g, the light sources 13h, and the light sources 13i are spaced apart in this order, relative to a given battery. Following these light sources 13g, 13h, and 13i, the light sources 13j, the light sources 13k, and the light sources 13l are spaced apart in this order, relative to a given battery. In such a configuration, three light sources emit light of the same wavelength, and in total, 36 (=12×3) light sources 13 that emit light of 12 different wavelengths are arranged.

The light sources 13a to 13l are preferably positioned along the outermost perimeter of the base 11. In such a manner, a given optical emission spectrometer 100 more easily receives light emitted from the light sources 13a to 13l. However, arrangement of the light sources 13a to 13l described above is not particularly restricted when such light sources are in the control board 12.

For the three light sources 13a of the same wavelength, it is preferable that measurement is performed in order of a middle-portion light source, one end-side light source from among the remaining two light sources, and another end-side light source. However, the one end-side light source, the another end-side light source, and the middle-portion light source are turned on in this order and measurement may be performed in sequence. Alternatively, the one end-side light source, the middle-portion light source, and the another end-side light source are turned on in this order and measurement may be performed in sequence. The same measurement order applies to three light sources of the same wavelength, from among the light sources 13b to 13l.

The jig, the processing system, and the processing method according to the embodiments in the present disclosure are examples and are not intended to be limiting in all respects. While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

The plasma processing apparatus in the present disclosure is applicable to an atomic layer deposition (ALD) apparatus. The plasma processing apparatus is also applicable to an apparatus using any one selected from among a capacitively coupled plasma (CCP), an inducibly coupled plasma (ICP), a radial line slot antenna (RLSA), an electron cyclotron resonance plasma (ECRP), and a helicon wave plasma (HWP).

According to one aspect of the present disclosure, analytic accuracy of emission intensity can be increased.

What is claimed is:

1. A jig comprising:
a base;
light sources disposed on the base, the sources being configured to emit light of different wavelengths;
a controller disposed on the base, the controller being configured to cause the light sources to be turned on or off based on a given program; and
a power source disposed on the base, the power source being configured to supply power to the light sources and the controller,
wherein the jig has a shape enabling a transfer device to transfer the jig, the transfer device being provided in a vacuum transfer module and configured to transfer a substrate.

2. The jig according to claim 1, wherein the base is a wafer.

3. The jig according to claim 1, wherein the jig is configured to be transferred between a given processing chamber and the vacuum transfer module, a reduced pressure environment being maintained.

4. The jig according to claim 1, wherein the light sources are disposed along the outermost perimeter of the base.

5. The jig according to claim 1, wherein the light sources include first light sources configured to emit light of a same wavelength, for each of the different wavelengths, the first light sources being arranged side by side.

6. The jig according to claim 1, wherein the light sources configured to emit light of the different wavelengths are spaced apart from each other.

7. The jig according to claim 1, wherein each light source has a wavelength range of from 200 nm to 850 nm.

8. The jig according to claim 1, wherein each light source includes an LED or an OLED.

9. The jig according to claim 1, further comprising a sensor.

10. The jig according to claim 1, wherein the jig includes a notch or an orientation flat for adjusting a direction in which the jig is disposed.

11. A processing system comprising:
a first information processing apparatus configured to perform a control to:
cause a jig to be disposed in a first processing chamber in a reference apparatus, the jig including:
a base;
light sources disposed on the base, the sources being configured to emit light of different wavelengths;
a controller disposed on the base, the controller being configured to cause the light sources to be turned on or off based on a given program; and
a power source disposed on the base, the power source being configured to supply power to the light sources and the controller; and
measure, as reference data, first data indicating emission intensity from light emitted from the light sources; and
a second information processing apparatus configured to perform a control to:
cause the jig to be disposed in a second processing chamber in a correction apparatus; and
measure second data indicating emission intensity from light emitted from the light sources;
obtain the reference data to compare the measured second data indicating the emission intensity with the reference data; and
correct the measured second data indicating the emission intensity based on a compared result.

12. The processing system according to claim 11, wherein the first information processing apparatus is configured to perform the control to cause the jig to be transferred between the first processing chamber of the reference apparatus and a vacuum transfer module, while maintaining a reduced pressure environment.

13. The processing system according to claim 11, wherein the second information processing apparatus is configured to perform the control to cause the jig to be transferred between the second processing chamber of the correction apparatus and a vacuum transfer module, while maintaining a reduced pressure environment of the second processing chamber.

14. The processing system according to claim 11, wherein the first information processing apparatus is a different information processing apparatus from the second information processing apparatus.

15. The processing system according to claim 11, wherein the first information processing apparatus is a same information processing apparatus as the second information processing apparatus.

16. A processing method comprising:
disposing a jig in a first processing chamber in a correction apparatus, the jig including:
a base;
light sources disposed on the base, the sources being configured to emit light of different wavelengths;
a controller disposed on the base, the controller being configured to cause the light sources to be turned on or off based on a given program; and
a power source disposed on the base, the power source being configured to supply power to the light sources and the controller; and
measuring first data indicating emission intensity from light emitted from the light sources; and
referencing a storage that stores, as reference data, second data indicating emission intensity from light emitted from the light sources, to compare the measured first data with the reference data, the second data being measured using the jig that is disposed in a second processing chamber in a reference apparatus; and
correct the measured first data based on a compared result.

17. The processing method according to claim 16, further comprising switching from a first light source for emitting light of a first wavelength, to a second light source for emitting light of a second wavelength different from the first wavelength, while rotating the jig at a given angle through an alignment device, the first light source and the second light source being from among the light sources; and
sequentially measuring the first data indicating the emission intensity from the switched light sources.

18. The processing method according to claim 16, further comprising measuring a temperature of given light sources through a sensor provided proximal to the given light sources; and
determining whether the measured temperature is greater than or equal to a predetermined threshold; and
interrupting emission from the given light sources upon determining that the measured temperature is greater than or equal to the predetermined threshold.

19. The processing method according to claim 16, further comprising transferring the jig between the first processing chamber of the correction apparatus and a vacuum transfer module, while maintaining a reduced pressure environment of the first processing chamber.

20. The processing method according to claim 16, further comprising transferring the jig between the second processing chamber of the reference apparatus and a vacuum transfer module, while maintaining a reduced pressure environment of the second processing chamber.
